(19) United States
(12) Patent Application Publication
(10) Pub. No.: US 2006/0027170 A1
(43) Pub. Date: Feb. 9, 2006

(54) Deposition boat and manufacturing method of organic EL display therewith

(75) Inventors: Yoshiro Takeda, Shiga (JP); Motohiko Asano, Shiga (JP); Katsuhiro Kaneko, Shiga (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/193,286

(22) Filed: Jul. 29, 2005

(30) Foreign Application Priority Data
Jul. 29, 2004 (JP) 221192/2004(PAT.)

(51) Int. Cl. C23C 16/00; B05D 5/06

(52) U.S. Cl. 118/726; 427/66; 427/248.1

(57) ABSTRACT

A deposition boat includes a boat on which a deposition material is placed; a cap body having an opening through which a vapor of the deposition material goes and partially overlapping with the boat; and a fixing member that is disposed on the overlapping portion of the cap body with the boat and fixes the cap body and boat at the overlapping portion, the fixing member being formed of a material that is more plastically deformable and higher in the fracture toughness than materials constituting the boat and the cap body.

### BACKGROUND OF THE INVENTION

1. Field of the Invention

The invention relates to a deposition boat used to heat and evaporate a deposition material, a manufacturing method of an organic EL display therewith and a manufacturing method of a deposition film therewith.

2. Description of the Related Art

In the vacuum deposition, a deposition boat is generally used to heat a deposition material in a vacuum to evaporate. The deposition boat is made of an electrically conductive material. In the deposition boat, a deposition material housed inside thereof is evaporated owing to the resistance heating when the deposition boat is energized, and the evaporated deposition material is deposited on a substrate disposed at a position opposite to the deposition boat to form a deposited film.

(1) JP unexamined Utility Model Publication No. 60-140760 (Patent literature 1)

In the patent literature 1, as an existing example of a deposition boat, a Knudsen boat is described (FIG. 7). The Knudsen boat is a sealed container provided with an evaporation port, and a vapor of a deposition material housed in the container is ejected from the evaporation port.

(2) JP unexamined Utility Model Publication No. 61-47066 (Patent literature 2)

In the patent literature 2, as an evaporation source heater (deposition boat) owing to resistance heating, which heats an evaporation source material to evaporate, an evaporation source heating heater 212 having a top boat 22 that has connecting terminals 22a, 22b at both ends and having an evaporation port 23 at a center thereof; and having a bottom boat 21 that has connecting terminals 21a, 21b at both ends and is provided with an evaporation source material (FIGS. 8A and 8B) is described. The top boat 22 and bottom boat 21 are disposed with the respective connecting terminals thereof overlapped together. Portions where the top boat 22 and bottom boat 21 are overlapped are welded to each other and the top boat 22 and the bottom boat 21 are integrated.

Furthermore, it is also described to engage the top boat 22 with the bottom boat 21 to integrate the top boat 22 and the bottom boat 21.

As a boat material, an electrically conductive refractory material such as tungsten, tantalum or the like is used.

(3) JP unexamined Patent Publication No. 11-246963 (Patent literature 3)

Patent literature 3 describes a deposition boat constituted of at least three members made of a top plate 31, a shielding plate 32 and a bottom plate 33 (FIG. 9) The top plate 31 and shielding plate 32, respectively, are provided with an opening 34, 35. In order to inhibit evaporating particles of a deposition material from immediately going outside of the deposition boat, the opening 34 and the opening 35 are disposed at different positions. Furthermore, when individual members are being assembled, the shielding plate 32 and the bottom plate 33 are slidable to each other, and in order to fix the respective members when these are assembled, a projection 36 is disposed on each of two long sides of the top plate 31. The projections 36 are folded toward the bottom plate 33 in a state where the top plate 31, the shielding plate 32 and the bottom plate 33 are assembled.

Accordingly, in the deposition boat, even when molten deposition material intrudes into the projection 36 owing to a capillary action, sputtered particles do not reach a substrate. As a result, there is no point defect in a film deposited by use of the deposition boat and owing to the uniformity of a film an excellent objective function can be exhibited.

Here, when a deposition material is heated to evaporate with a deposition boat, the deposition boat made of a material suitable for the deposition material is properly selected. For instance, at temperatures where the deposition material is evaporated, a constituent material of the deposition boat is necessary to be sufficiently stable, and a material that causes a chemical reaction between the deposition material and the deposition boat when the deposition material is heated has to be avoided to select.

In an existing deposition boat, in the case of a material high in the reactivity such as calcium being used as a deposition material, when the deposition boat is formed with tantalum, when the deposition boat is heated, tantalum and calcium react. Accordingly, as a material of the deposition boat, in many cases, tungsten that is high in the melting point and free from a problem of reacting with calcium is used.

However, tungsten is a material that is hard, brittle and difficult to process. Accordingly, there is a problem in that it is very difficult to form, to a cap and a boat, an engaging portion where, in order to fix a cap body (top boat) and a boat (bottom boat), both are stacked and integrated.

Furthermore, not only in the case where as a material of the deposition boat tungsten is used, but also in the case where hard or brittle materials such as carbon, chromium, cobalt and vanadium are used, there are similar problems.

### SUMMARY OF THE INVENTION

A deposition boat according to the invention includes a boat on which a deposition material is placed; a cap body having an opening through which a vapor of the deposition material goes and overlapping partially with the boat; and a fixing member that is disposed on the overlapping portion of the boat and the cap body and fixes the boat and the cap body at the overlapping portion, the fixing member being formed of a material that is more plastically deformable and higher in the fracture toughness than materials constituting the boat and the cap body.

Furthermore, a manufacturing method of an organic EL display according to the invention includes preparing the foregoing deposition boat, the deposition material placed on the deposition boat and a display substrate disposed above the deposition boat; and heating the deposition boat to evaporate the deposition material, and thereby depositing the evaporated material on the display substrate to form on the display substrate an organic luminescent layer and/or an electrode layer.

### BRIEF DESCRIPTION OF THE DRAWINGS

FIG. 1A is a sectional view showing an embodiment of a deposition boat according to the invention, FIG. 1B being a plan view of FIG. 1A.

FIGS. 2A and 2B are sectional views showing another embodiment of a deposition boat according to the invention.

FIG. 3 is a sectional view showing still another embodiment of a deposition boat according to the invention.

FIG. 4 is a sectional view showing another embodiment of a deposition boat according to the invention.

FIGS. 5A and 5B are plan views showing shielding members of a deposition boat according to the invention.

FIG. 6 is a sectional view showing a manufacturing method of an organic EL display according to the invention.

FIG. 7 is a sectional view showing an existing deposition boat.

FIG. 8A is an exploded perspective view showing an existing deposition boat, FIG. 8B being a perspective view showing an existing deposition boat.

FIG. 9 is an exploded perspective view showing an existing deposition boat.

### DETAILED DESCRIPTION OF THE INVENTION

In what follows, a deposition boat according to the invention will be detailed with reference to the drawings.

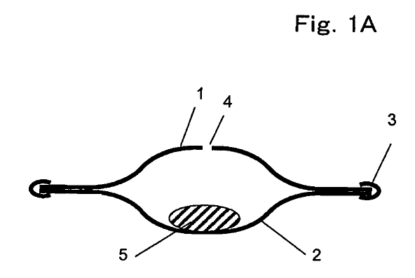

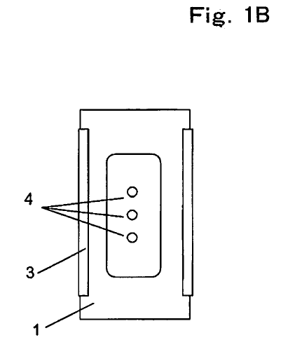

FIG. 1A is a sectional view of an embodiment of a deposition boat according to the invention, and FIG. 1B is a plan view of FIG. 1A. In FIGS. 1A and 1B, reference numerals 1, 2, 3, 4 and 5, respectively, denote a cap body, a boat, a fixing member, a plurality of openings formed in the cap body 1 and a deposition material.

At a center portion of each of the cap body 1 and boat 2, a dent is formed, and with the dents a hollow portion for housing the deposition material 5 is formed between the cap body 1 and the boat 2. The cap body 1 and the boat 2 are overlapped at both ends thereof with each other. The overlapped portion is sandwiched with the fixing member 3 to fix, and thereby the cap body 1 and the boat 2 are integrated. Of the overlapped portions of the cap body 1 and the boat 2, portions that are not fixed with the fixing member 3, respectively, are provided with a negative electrode and a positive electrode (not shown in the drawing) for energization. When the boat 2 is energized through the negative electrode and positive electrode, the boat 2 is heated and thereby the deposition material 5 placed on the boat 2 is evaporated. The evaporated deposition material 5 is discharged outside through the openings 4 formed to the cap body 1 and thereby deposited on a substrate disposed above the deposition boat. As a result, a deposition film is formed on the substrate.

The cap body 1 is formed from an electrically conductive refractory material that is difficult to bend or fold with a small curvature and difficult to process because of the hardness and the brittleness. As the electrically conductive refractory materials, like a simple body such as tungsten, molybdenum, chromium, cobalt and vanadium or alloys containing these, ones having a sufficiently higher melting point than a temperature where the deposition material 5 is evaporated and difficult to react with the deposition material 5 can be properly used.

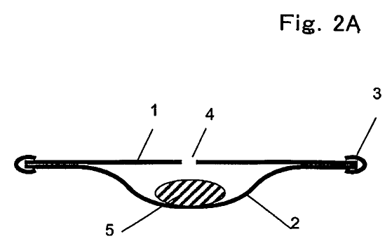

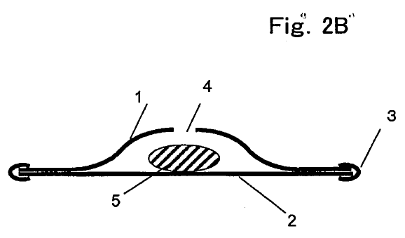

At end portions of the cap body 1, a flat portion is formed to overlap with the boat 2, and at a center of the cap body 1 a dent for forming a hollow portion housing the deposition material 5 between the cap body 1 and boat 2 is formed. The cap body 1 may be a tabular one such as one that is shown in FIG. 2A and does not have a dent. Furthermore, like in FIG. 2B, the cap body 1 is formed with a dent and the boat 2 is formed tabular, and thereby a hollow portion may be formed between the boat 2 and cap body 1. When either of the cap body 1 or boat 2 is formed planar, the cap body 1 or boat 2 can be processed conveniently; accordingly, the productivity of the deposition boat can be improved. Furthermore, when either of the cap body 1 or boat 2 is formed planar, since the electric resistance of the deposition boat 2 becomes smaller, the deposition material in the deposition boat can be efficiently heated and evaporated at lower electric currents and electric powers.

The openings 4 formed in the cap body 1 are one where, when the deposition material 5 placed on the boat 2 is evaporated, evaporated deposition particles go through. The openings 4 are formed circular or rectangular. A diameter or width of the openings 4 are preferably in the range of 0.5 to 2 mm. In the case of the openings 4 being excessively large, when the deposition material 5 is heated and bumps in the deposition boat 2, the deposition material 5 is discharged from the openings 4 in block, and thereby the irregularities in a film thickness of a layer formed on the substrate or a denatured film or wastage of the deposition material 5 is caused. On the other hand, in the case of the openings 4 being too small, an amount of discharge of the deposition particles that go through the openings 4 become smaller and thereby the deposition speed becomes very small, resulting in lowering the productivity or becoming difficult to process the openings 4. The number or arrangement of the openings 4, in order that a desired deposition speed and deposition distribution may be obtained, may well be properly designed and manufactured based on experiments and simulations.

In the case of the cap body 1 being formed of tungsten, the cap body 1 can be manufactured firstly by adopting a processing method such as drawing or pressing a planar body made of tungsten to process the planar body into a predetermined shape having a dent, followed by forming openings 4 in the plate with a drill or the like.

On an inner surface of the cap body 1, a surface modification layer constituted of boron nitride, alumina, zirconia or carbides or nitrides of electrically conductive refractory materials may be formed. In the case of the surface modification layer being formed on an inner surface of the cap body 1, the corrosion resistance and the reaction resistance of the cap body 1 become stronger. The surface modification layer can be applied by directly carbonizing or nitriding by adopting a method where a surface of cap body 1 is brought into contact with carbon and heated to carbonize, or a method of nitriding by heating or plasma discharging in a nitrogen atmosphere, by coating by means of a sputtering method or an ion plating method, or by sintering.

The boat 2 works as a support for supporting the deposition material 5. The boat 2 is formed of a hard and brittle electrically conductive refractory material that is difficult to bend or fold at a small curvature. As the electrically conductive refractory materials, materials such as a simple body such as tungsten, molybdenum, chromium, cobalt and vanadium or alloys containing these, which have a melting point sufficiently higher than a temperature where the deposition material 5 is evaporated and are difficult to react with the deposition material 5 can be properly used.

At end portions of the boat 2, a flat portion is formed so as to overlap with the cap body 1, and at a center of the boat 2 a dent for forming a hollow portion that houses the deposition material 5 between the cap body 1 and the boat 2 is formed.

The boat 2, when it is formed of tungsten, can be manufactured by adopting a method such as drawing or pressing to process a planar body made of tungsten to form into a predetermined shape having a dent.

Furthermore, on an inner surface of the boat 2, a surface modification layer constituted of boron nitride, alumina, zirconia or carbides or nitrides of electrically conductive refractory materials may be formed. In the case of the surface modification layer being formed on an inner surface of the boat 2, the corrosion resistance and the reaction resistance of the boat 2 become stronger. When the surface modification layer is constituted of carbide, the surface modification layer can be formed by a method where an inner surface of the boat 2 is heated, while being brought into contact with carbon, for carbonization. Furthermore, the surface modification layer, when it is constituted of nitride, can be formed according to a method where the inner surface of the boat 2 is heated or plasma discharged in a nitrogen atmosphere to nitride. Still furthermore, as another method of forming a surface modification layer, there are a sputtering method and ion plating method.

At the overlapping portions of the cap body 1 and the boat 2, a pair of fixing members 3 is disposed. The fixing member 3 has a sandwiching portion that sandwiches the overlapping portion of the cap body 1 and the boat 2 to fix the cap body 1 and the boat 2.

The fixing member 3 is made of a refractory material that is more plastic deformable and higher in the fracture toughness than the cap body 1 and the boat 2. For instance, alloys containing tantalum, SUS, nickel, platinum, tungsten, molybdenum, chromium, cobalt and vanadium can be cited.

Now, the plastic deformable material means a material where a ratio of the elongation at break (%) to the elongation at yield (%) (elongation at break/elongation at yield) measured based on a tensile test method (JIS Z2241) is large. Furthermore, a material high in the fracture toughness means a material where a ratio of the tensile stress (MPa) to the yield stress (MPa) (tensile stress/yield stress) measured based on a tensile test method (JIS Z2241) is large.

Furthermore, by making the thermal expansion coefficient of the fixing material 3 smaller than that of members of the cap body 1 and the boat 2, when the deposition boat is energized and heated, owing to the difference of the thermal expansion coefficients between the fixing member 3 and the cap body 1 and the boat 2, these members may be rendered so as to be fixed more stronger.

It is preferable that, in order to assuredly fix the cap body 1 and the boat 2, 1 mm or more inside (toward a center of the boat 2) from an end of the overlapping portion of the cap body 1 and the boat 2, a tip end of the sandwiching portion of the fixing member 3 is located.

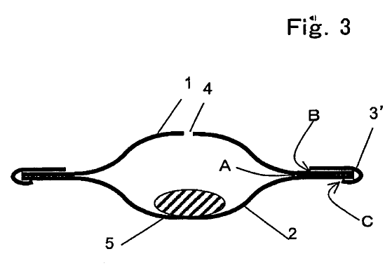

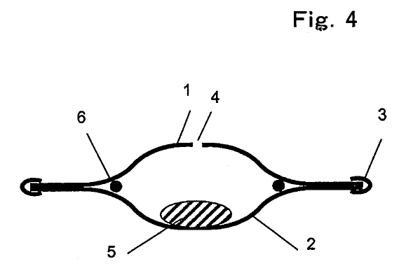

Furthermore, as shown in FIG. 3, when, of the sandwiching portion of the fixing member 3, an end of a second pressing portion that presses the cap body 1 is located more inside (toward the center of the boat 2) than an end of a first pressing portion that presses the boat 2, in the case where during heating the deposition material 5 an internal pressure of the deposition boat becomes higher and vapor leaks from a gap A formed at the overlapping portion of the cap body 1 and boat 2, the vapor leaked from the gap A is easier to pass a gap C between the fixing member 3 and the boat 2 than a gap B between the fixing member 3 and the cap body 1. As a result, the vapor within the boat is suppressed from leaking toward the substrate disposed above, and thereby a layer formed on the substrate can be inhibited from fluctuating in the film thickness and causing a denatured film.

The end of the second pressing portion is preferably located three times or more toward a center of the boat 2 than the end of the first pressing portion.

The fixing member 3 can be prepared by processing a predetermined planar body according to a well-known bending method.

In the deposition boat thus obtained according to the invention, electric power is supplied through a positive electrode and a negative electrode to the cap body 1 and the boat 2, and thereby the boat 2 is heated to evaporate the deposition material 5. Then, vapor of the evaporated deposition material 5 is discharged through the openings 4 toward the substrate above the deposition boat 2, and the discharged deposition material is piled up on the substrate to form a deposition film on the substrate.

According to the deposition boat according to the invention, since the boat 2 and the cap body 1 can be readily fixed with the fixing member 3, unlike the conventional deposition boat, there is no need of forcibly engaging the boat 2 with the cap body 1. Accordingly, even when the boat 2 and cap body 1 are formed of a material difficult to process such as tungsten, there is no need of forming both into a complicated shape to form an engaging portion to each of the boat 2 and cap body 1; accordingly, the deposition boats can be improved in the productivity thereof.

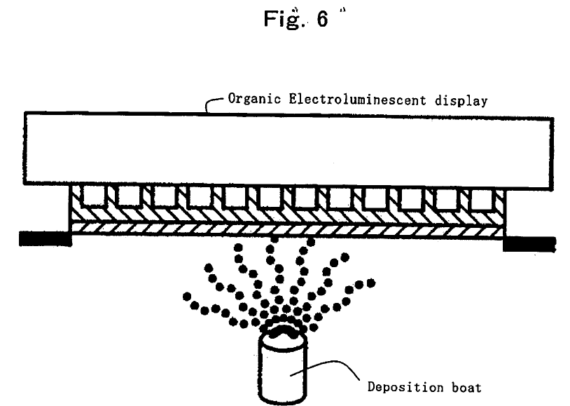

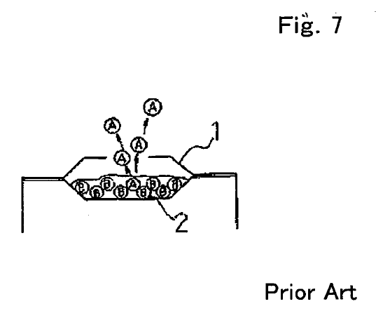

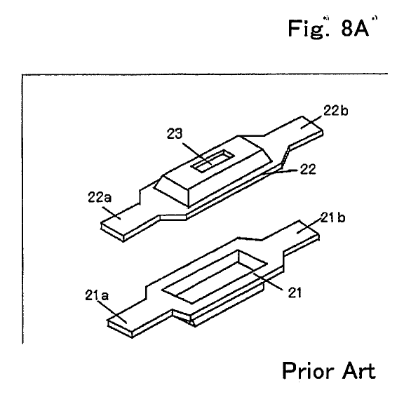

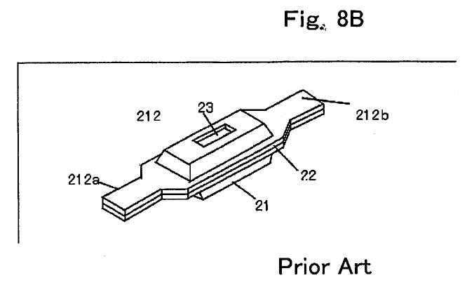

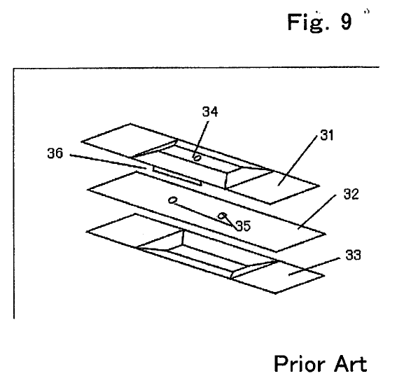

Furthermore, according to the deposition boat according to the invention, the boat 2 can be made of a material such as tungsten or alumina that is difficult to react with the deposition material; accordingly, a concentration of impurities mingled in the deposition film formed on the substrate can be suppressed low. Accordingly, as shown in FIG. 6, when the deposition boat according to the invention is used to form an organic layer and an electrode layer of an organic EL display, a concentration of the impurities mingled in the organic layer or the electrode layer can be suppressed low, resulting in providing high performance organic EL displays.

Still furthermore, according to the deposition boat according to the invention, since the boat 2 can be formed of a material such as tungsten or alumina that is difficult to react with the deposition material, alkali metals or alkaline earth metals such as calcium, Sr, Mg, Be and Li that are readily react with other materials can be used as the deposition material 5, resulting in expanding a range of selection of deposition films.

Furthermore, according to the invention, when the cap body 1 or the boat 2 is formed planar in the hollow portion, the cap body 1 or boat 2 can be made convenient to process, resulting in an improvement in the productivity of the deposition boats. Furthermore, when the cap body 1 or the boat 2 is formed planar, since the electric resistance of the deposition boat becomes smaller, the deposition material 5 in the deposition boat can be efficiently heated and evaporated at a lower electric current and electric power.

The invention is not restricted to the foregoing embodiments and can be variously changed and improved within a gist of the invention.

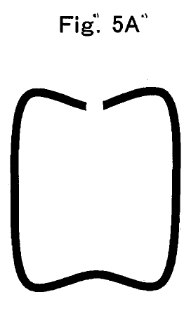

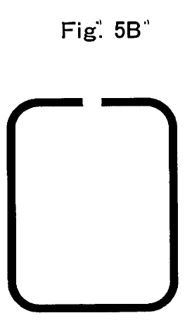

For instance, in the foregoing embodiments, along an outer periphery of a hollow portion formed with the cap body 1 and the boat 2, a shielding member 6 as shown in FIG. 5A or 5B may be disposed and brought into contact with inner surfaces of the cap body 1 and boat 2. The shielding member 6 inhibits vapor of the deposition material 5 from leaking outside through the gaps A at the overlapping portions of the cap body 1 and boat 2. As the shielding member 6, a wire made of a refractory material is preferably disposed circularly. A diameter of the wire is preferably in the range of 0.5 to 2 mm. This is because when the diameter of the wire is smaller than 0.5 mm, the shielding effect owing to the shielding member 6 tends to become smaller. When the diameter of the wire is larger than 2 mm, the wire can be bent with difficulty and a spatial volume in the deposition boat is lowered. A material of the shielding member 6 is preferably a refractory material such as tungsten, tantalum, molybdenum and chromium.

Furthermore, in the embodiment, a plurality of the fixing members 3 may be disposed along the overlapping portions of the cap body 1 and the boat 2.

Still furthermore, in the embodiment, a plurality of the openings 4 is provided to the cap body 1; however, in place of this, only one opening 4 may be provided to the cap body 1.

### EXAMPLE

In the next place, a specific example of the deposition boat according to the invention will be described.

A tungsten plate having a thickness of 0.2 mm was processed to form a dent having a length of 70 mm, a width of 20 mm and a depth of 7 mm at a center thereof, and thereby a boat having a length of 100 mm and a width of 30 mm and a cap body having a shape same as the boat were prepared. Furthermore, three openings having a diameter of 1.0 mm were drilled in the proximity of the center at 10 mm intervals. Furthermore, with a tantalum plate having a thickness of 0.2 mm, fixing members having an inner curvature of substantially 1 mm, a width of 2 mm and a length of 70 mm were prepared. The boat and cap body were overlapped, the overlapped portions were fixed with the fixing members, and thereby a deposition boat as shown in FIG. 1 was prepared. As to the overlapping portions of the boat and the cap body, a width of a portion fixed by the fixing member was set at substantially 5 mm. As a deposition material placed in the dent of the boat, 2 g of calcium was used.

The obtained deposition boat was connected and fixed to a positive electrode and a negative electrode in a vacuum chamber so as to sandwich both ends of the deposition boat up and down. After evacuating to substantially 1×10⁻⁴ Pa, a direct current was supplied to the deposition boat between the positive electrode and the negative electrode to heat the deposition boat, and thereby the degassing was sufficiently carried out. When, while monitoring a deposition rate by use of a quartz oscillator, calcium that is a deposition material was evaporated, stable deposition rates within substantially ±0.1 A/sec were obtained at 0.5 A/sec at a current value of substantially 270 A, 1.0 A/sec at a current value of 280 A and at 1.5 A/sec at a current value of 285 A. At this time, the anomaly such as the bumping was not observed. A thickness of a calcium film deposited on a glass substrate disposed so as to face the deposition boat exhibited such excellent in-plane uniformity as ±5% or less within a plane of 40 cm×35 cm.

Furthermore, when, after all calcium was evaporated, the deposition boat was decomposed to confirm the inside, there was found no anomaly on a surface of tungsten, and the deposition boat could be reused. Still furthermore, although calcium leaked through the gaps at the overlapping portions of the boat and cap body, it was within a permissible range.

What is claimed is:

1. A deposition boat, comprising:
a boat on which a deposition material is placed;
a cap body having an opening through which a vapor of the deposition material goes and partially overlapping with the boat; and
a fixing member that is disposed on the overlapping portion of the boat with the cap body and fixes the boat and the cap body at the overlapping portion;
wherein the fixing member is formed of a material that is more plastically deformable and higher in the fracture toughness than materials constituting the boat and the cap body.

2. The deposition boat according to claim 1, wherein the deposition material is housed in a hollow portion formed between the boat and the cap body.

3. The deposition boat according to claim 1, wherein the boat and the cap body are formed of an electrically conductive material.

4. The deposition boat according to claim 1, wherein the boat and the cap body are formed of tungsten.

5. The deposition boat according to claim 1, wherein the fixing member is formed of tantalum.

6. The deposition boat according to claim 1, wherein the fixing member has a sandwiching portion that sandwiches the boat and the cap body.

7. The deposition boat according to claim 6, the sandwiching portion comprising a first pressing portion that presses the boat and a second pressing portion that presses the cap body, wherein the second pressing portion is located more toward a center of the boat than the first pressing portion.

8. The deposition boat according to claim 2, wherein the cap body or the boat is formed planar in the hollow portion.

9. The deposition boat according to claim 2 further comprising: a shielding member that is disposed along an outer periphery of the hollow portion and brought into contact with inner surfaces of the boat and the cap body.

10. The deposition boat according to claim 9, wherein the shielding member is made of tungsten.

11. A manufacturing method of a deposition film, comprising:
preparing the deposition boat described in claim 1, the deposition material placed on the deposition boat and a substrate disposed above the deposition boat; and
heating the deposition boat to evaporate the deposition material, and thereby depositing the evaporated material on the substrate to form on the substrate a deposition film.

12. A manufacturing method of an organic EL display, comprising:
preparing the deposition boat described in claim 1, the deposition material placed on the deposition boat and a display substrate disposed above the deposition boat; and
heating the deposition boat to evaporate the deposition material, and thereby depositing the evaporated material on the display substrate to form on the display substrate an organic luminescent layer and/or an electrode layer.
